(19) United States
(12) Patent Application Publication
(10) Pub. No.: US 2020/0295078 A1
(43) Pub. Date: Sep. 17, 2020

(54) SOLID-STATE IMAGING DEVICE

(71) Applicants: Kabushiki Kaisha Toshiba, Tokyo (JP); Toshiba Electronic Devices & Storage Corporation, Tokyo (JP)

(72) Inventor: Yasushi Itabashi, Kita Tokyo (JP)

(21) Appl. No.: 16/561,647

(22) Filed: Sep. 5, 2019

(30) Foreign Application Priority Data
Mar. 11, 2019 (JP) 2019-044028

(51) Int. Cl. H01L 27/148; H04N 5/372; H01L 23/00

(52) U.S. Cl. CPC H01L 27/14806; H04N 5/372; H01L 23/562; H01L 27/14818; H01L 27/14831

(57) ABSTRACT

A solid-state imaging device includes a light detector provided inside a semiconductor body; a first insulating film provided on a front surface of the semiconductor body; a plurality of second insulating films provided between the light detector and the first insulating film, the plurality of second insulating films arranged in a first direction along the front surface of the semiconductor body; and a third insulating film provided between the semiconductor body and the second insulating films, the third insulating film having a refractive index lower than a refractive index of the second insulating films.

### CROSS-REFERENCE TO RELATED APPLICATIONS

This application is based upon and claims the benefit of priority from Japanese Patent Application No. 2019-044028, filed on Mar. 11, 2019; the entire contents of which are incorporated herein by reference.

### FIELD

Embodiments relate to a solid-state imaging device.

### BACKGROUND

A solid-state imaging device has a structure in which multiple pixels are provided in a semiconductor body such as silicon or the like. The solid-state imaging device may achieve higher sensitivity by increasing the light amount entering each pixel. Thus, it is important to provide, for example, an anti-reflection film to reduce the light loss due to reflections at the silicon surface. However, there may be a case where the dark output increases in the pixel to which the anti-reflection film is applied, and reduces the sensitivity.

### BRIEF DESCRIPTION OF THE DRAWINGS

FIGS. 1A and 1B are schematic views showing a solid-state imaging device according to a first embodiment;

FIGS. 2A and 2B are schematic views showing a solid-state imaging device according to a comparative example;

FIG. 3 is a schematic view showing a solid-state imaging device according to a modification of the first embodiment; and

FIGS. 4A and 4B are schematic views showing a solid-state imaging device according to a second embodiment.

### DETAILED DESCRIPTION

According to one embodiment, a solid-state imaging device includes a light detector provided inside a semiconductor body; a first insulating film provided on a front surface of the semiconductor body; a plurality of second insulating films provided between the light detector and the first insulating film, the plurality of second insulating films arranged in a first direction along the front surface of the semiconductor body; and a third insulating film provided between the semiconductor body and the second insulating films, the third insulating film having a refractive index lower than a refractive index of the second insulating films.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

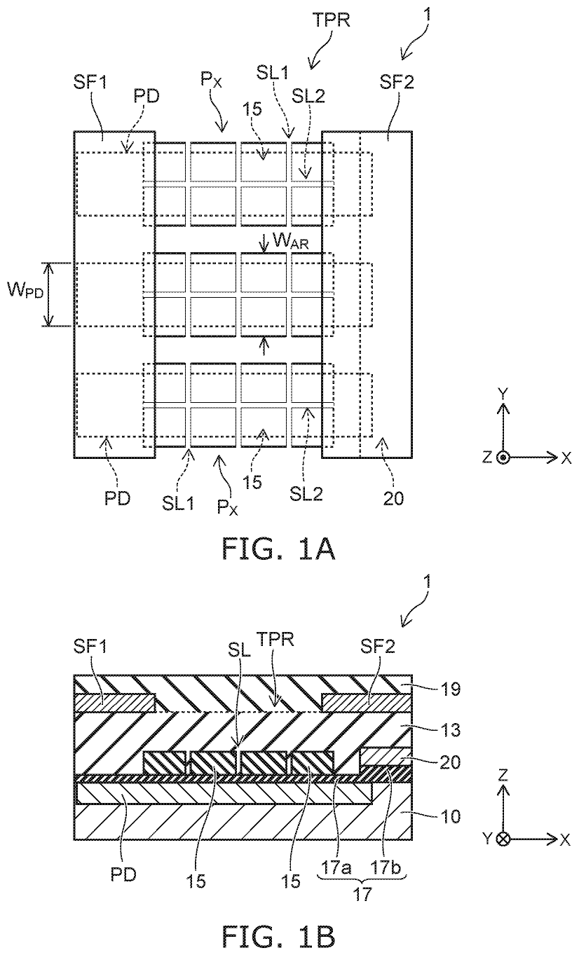

FIGS. 1A and 1B are schematic views showing a solid-state imaging device 1 according to a first embodiment. The solid-state imaging device 1 is, for example, a Charge Coupled Device (CCD). FIG. 1A is a plan view showing the arrangement of pixels P_{X} of the solid-state imaging device 1. FIG. 1B is a cross-sectional view showing the structure of the pixel P_{X} of the solid-state imaging device 1.

As shown in FIG. 1A, the solid-state imaging device 1 includes the pixels P_{X}, a light-shielding film SF1, and a light-shielding film SF2. For example, the pixels P_{X} are arranged in a transparent region TPR between the light-shielding film SF1 and the light-shielding film SF2. The light-shielding films SF1 and SF2 are, for example, aluminum films, and extend in the Y-direction. The pixels P_{X} are arranged in the Y-direction in the transparent region TPR.

As shown in FIG. 1B, in the solid-state imaging device 1, a pixel P_{X} includes a light detector PD, a first insulating film 13, a second insulating film 15, and a third insulating film 17.

The light detector PD is provided inside a semiconductor body, e.g., a semiconductor substrate 10. The semiconductor substrate 10 is, for example, a silicon substrate. The light detector PD is, for example, a photodiode, which includes a p-type semiconductor and an n-type semiconductor. The light detector PD has, for example, the long side along the X-direction and the short side along the Y-direction (see FIG. 1A).

The first insulating film 13 is provided on the front surface of the semiconductor substrate 10. The first insulating film 13 is, for example, a silicon oxide film. The light-shielding films SF1 and SF2 are provided on the first insulating film 13. The first insulating film 13 is provided between the light-shielding film SF1 and the semiconductor substrate 10 and between the light-shielding film SF2 and the semiconductor substrate 10. The first insulating film 13 also includes a portion positioned in the transparent region TPR between the light-shielding film SF1 and the light-shielding film SF2 when viewed along the Z-direction.

The second insulating film 15 is provided between the light detector PD and the first insulating film 13. The second film 15 is provided in a plurality. The plurality of second insulating films 15 are arranged in a first direction (e.g., the X-direction) with slits SL interposed. The first direction is, for example, a direction along the front surface of the semiconductor substrate 10. The second insulating film 15 is, for example, silicon nitride film, and has a refractive index higher than the refractive index of the first insulating film 13. For example, the second insulating film 15 has a thickness of 500 angstroms (Å) in the Z-direction. For example, the slits SL have widths in the range of 0.2 to 0.4 micrometers (μm) in a direction along the front surface of the semiconductor substrate 10 (i.e., the X-direction or the Y-direction). The plurality of second insulating films are arranged in two rows along the X-direction (see FIG. 1A).

The third insulating film 17 is provided between the semiconductor substrate 10 and the second insulating films 15. The third insulating film 17 is, for example, a silicon oxide film, and has a refractive index lower than the refractive index of the second insulating films 15.

The solid-state imaging device 1 further includes a control electrode 20 and an insulating film 19. For example, the control electrode 20 is provided on the outer edge of the light detector PD. For example, the control electrode 20 is placed between the semiconductor substrate 10 and the light-shielding film SF2. The control electrode 20 electrically connects the light detector PD and a charge transfer portion (not illustrated). The insulating film 19 is provided to cover the light-shielding film SF1, the light-shielding film SF2, and the first insulating film 13. The insulating film 19 is, for example, a silicon oxide film.

The third insulating film 17 includes a first portion 17a and a second portion 17b. The first portion 17a is positioned between the semiconductor substrate 10 and the second insulating films 15. The second portion 17b is positioned between the semiconductor substrate 10 and the control electrode 20. The second portion 17b is provided to be thicker than the first portion 17a in a direction perpendicular to the front surface of the semiconductor substrate 10 (i.e., the Z-direction). For example, the second portion 17b is provided to have a thickness of 500 Å in the Z-direction. For example, the first portion 17a is provided to have a thickness of 100 Å in the Z-direction.

For example, the solid-state imaging device 1 operates by sending the electron to the charge transfer portion (not illustrated) through a channel induced in the front surface of the semiconductor substrate 10, which are excited by the light entering the light detector PD. The control electrode 20 functions as a gate electrode which induces the channel in the front surface of the semiconductor substrate 10; and the second portion 17b of the third insulating film 17, for example, serves as the gate insulating film.

To increase the sensitivity of the solid-state imaging device 1, it is desirable to increase the light amount that passes through the transparent region TPR and enters each pixel P_{X}. In the embodiment, the second insulating films 15 that have a larger refractive index than the third insulating film 17 are provided to reduce the light not entering the light detector PD due to reflections at the interface between the light detector PD and the third insulating film 17. That is, the light reflected at the interface between the light detector PD and the third insulating film 17 is reflected again at the interface between the third insulating film 17 and the second insulating films 15, and returns toward the light detector PD. Thereby, it is possible to make the sensitivity of the pixel P_{X} higher by increasing the light amount entering the light detector PD.

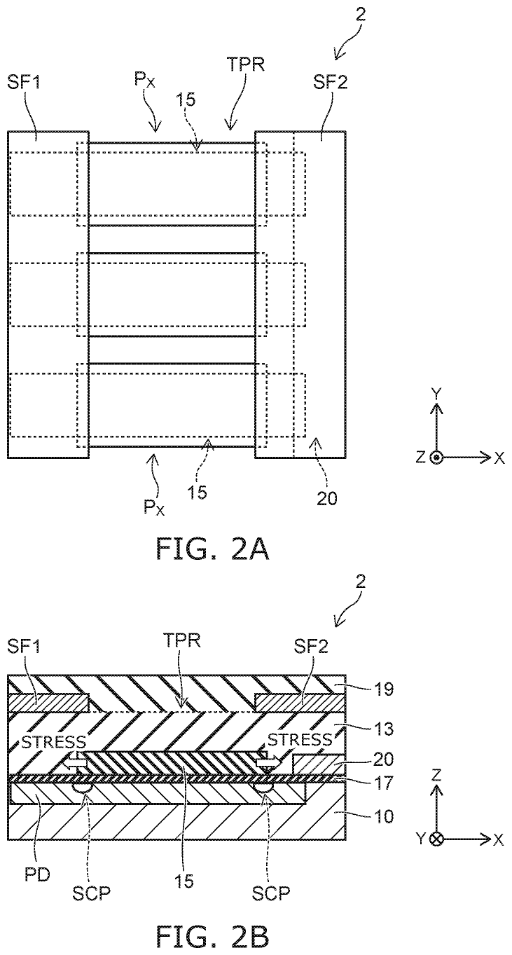

FIGS. 2A and 2B are schematic views showing a solid-state imaging device 2 according to a comparative example. FIG. 2A is a plan view showing the arrangement of pixels P_{X} in the solid-state imaging device 2. FIG. 2B is a cross-sectional view showing a structure of the pixel P_{X} in the solid-state imaging device 2. Other than the pixel P_{X}, the solid-state imaging device 2 has the same structures as those of the solid-state imaging device 1.

In the solid-state imaging device 2, the pixel P_{X} includes the third insulating film 17, the second insulating film 15, the first insulating film 13, and the light detector PD that is provided in the semiconductor substrate 10. The second insulating film 15 is positioned between the light detector PD and the first insulating film 13; and the third insulating film 17 is positioned between the light detector PD and the second insulating film 15.

The third insulating film 17 is, for example, a silicon oxide film formed by thermal oxidation of the silicon substrate. For example, the second insulating film 15 is a silicon nitride film deposited on the third insulating film 17 by Chemical Vapor Deposition (CVD).

In the second insulating film 15 of the solid-state imaging device 2, stress is generated due to the differences of the linear thermal expansion coefficient between the semiconductor substrate 10 and the second insulating film 15. For example, in the case where the second insulating film 15 is a silicon nitride film, the second insulating film 15 has a tensile stress of 200 to 300 megapascals (MPa). For example, the stress concentrates at the end portions of the second insulating film 15; and stress concentration portions SCP are generated in the semiconductor substrate 10.

For example, the lattice strain of silicon crystal is generated at the stress concentration portion SCP. When the stress concentration portion SCP is positioned inside the light detector PD, the electrons generated by thermal excitation increases; and the dark output of the pixel P_{X} increases. For example, the dark output of the pixel P_{X}, increases to 1.5 times the dark output in the case where the stress concentration portion SCP is not positioned inside the light detector PD; and the sensitivity of the pixel P_{X} degrades.

As shown in FIG. 1A, the second insulating films 15 are subdivided into a plurality by slits SL1 and SL2 in the solid-state imaging device 1 according to the embodiment. Therefore, the stress is dispersed in the second insulating films 15; and the lattice strain can be suppressed in the semiconductor substrate 10. The sensitivity of the pixel P_{X} can be increased thereby.

The slits SL1 and SL2 may be provided to have a depth not enough to completely subdivide the second insulating film 15, i.e., a depth not enough to reach the third insulating film 17 from the front surface of the second insulating film 15 on the first insulating film 13 side.

In the example shown in FIG. 1A, the second insulating film 15 is subdivided into a plurality by the slit SL1; and the plurality of second insulating films 15 are arranged in the X-direction. The second insulating films 15 are further subdivided by the slit SL2, and are arranged also in the Y-direction.

The embodiment is not limited to the example. For example, in the example shown in FIG. 1A, the end portions in the Y-direction of the second insulating film 15 are positioned outside the light detector PD. That is, in the case where the slit SL2 is not provided, a width W_{AR} in the Y-direction of the second insulating film 15 is wider than a width W_{PD} in the Y-direction of the light detector PD. There is lower risk of making the dark output of the pixel P_{X} increase, when the stress concentration portion SCP is positioned outside the light detector PD. Accordingly, the slit SL2 can be omitted, which subdivides the second insulating film 15 in the Y-direction,

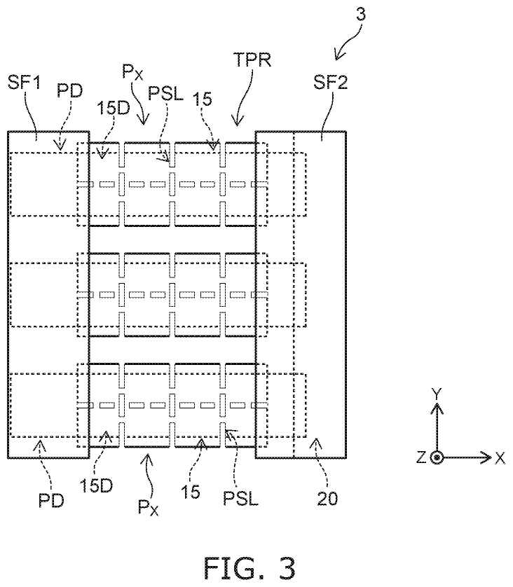

FIG. 3 is a schematic view showing a solid-state imaging device 3 according to a modification of the first embodiment. FIG. 3 is a plan view showing the arrangement of the pixels P_{X}. Other than the second insulating film 15, the solid-state imaging device 3 has the same structures as those of the solid-state imaging device 1.

The second insulating film 15 is selectively provided between the first insulating film 13 and the third insulating film 17 (referring to FIG. 1B) and has a refractive index higher than the refractive index of the third insulating film 17. For example, the second insulating film 15 has a thickness of 500 Å in the Z-direction. For example, the second insulating film 15 has the length along the X-direction, which is shorter than the length of the light detector PD along the X-direction.

As shown in FIG. 3, the second insulating film 15 includes a slit PSL having a hole configuration. For example, the slit PSL is provided to extend through the second insulating film 15 in the direction from the first insulating film 13 toward the third insulating film 17 (the −Z direction). For example, the slit PSL has a width in the range of 0.2 to 0.4 μm in a direction along the front surface of the semiconductor substrate 10 (the X-direction or the Y-direction). The slit PSL may be provided to have a depth not enough to reach the third insulating film 17.

For example, the slit PSL is arranged in the X-direction and the Y-direction along the front surface of the semiconductor substrate 10. Multiple columns of the slits PSL are arranged in the X-direction, in which the slits PSL are arranged in the Y-direction.

In the example shown in FIG. 3, there is one column of the slits PSL arranged in the X-direction; but multiple such columns may be arranged in the Y-direction. Also, the column of the slits PSL arranged in the X-direction may be omitted.

In the example, the stress can be reduced by arranging the multiple slits PSL in the second insulating film 15; and the lattice strain can be suppressed in the semiconductor substrate 10. Thereby, the dark output of the pixel P_{X} can be reduced; and the sensitivity of the pixel P_{X} can be increased.

### Second Embodiment

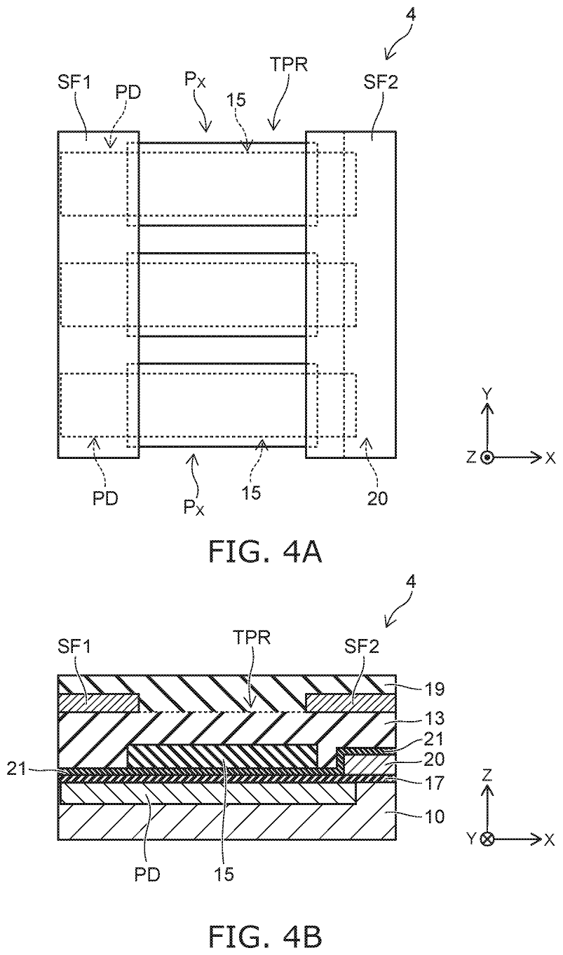

FIGS. 4A and 4B are schematic views showing a solid-state imaging device 4 according to a second embodiment. FIG. 4A is a plan view showing the arrangement of the pixels P_{X} in the solid-state imaging device 4. FIG. 4B is a cross-sectional view showing the structure of the pixel P_{X} in the solid-state imaging device 4.

In the solid-state imaging device 4, as shown in FIG. 4A, the arrangement of the pixels P_{X} in the transparent region TPR between the light-shielding film SF1 and the light-shielding film SF2 is the same as that of the solid-state imaging device 1. The second insulating film 15 of the solid-state imaging device 4 does not include the slits SL or PSL.

As shown in FIG. 4B, the solid-state imaging device 4 includes the light detector PD, the first insulating film 13, the second insulating film 15, the third insulating film 17, and a fourth insulating film 21.

The first insulating film 13 is provided above the semiconductor substrate 10. The first insulating film 13 is, for example, a silicon oxide film. The first insulating film 13 is provided between the light-shielding film SF1 and the semiconductor substrate 10 and between the light-shielding film SF2 and the semiconductor substrate 10. The first insulating film 13 also includes a portion positioned in the transparent region TPR between the light-shielding film SF1 and the light-shielding film SF2 when viewed in the Z-direction.

The second insulating film 15 is provided between the light detector PD and the first insulating film 13. For example, the second insulating film 15 has a refractive index higher than the refractive index of the first insulating film 13. The second insulating film 15 is, for example, a silicon nitride film. For example, the second insulating film 15 has a thickness of 500 Å in the Z-direction.

The third insulating film 17 is provided between the semiconductor substrate 10 and the second insulating film 15. The third insulating film 17 is, for example, a silicon oxide film and has a refractive index lower than the refractive index of the second insulating film 15. The third insulating film 17 includes a portion positioned between the semiconductor substrate 10 and the control electrode 20. For example, the third insulating film 17 has a thickness in the Z-direction of 100 Å at the portion positioned between the light detector PD and the second insulating film 15.

The fourth insulating film 21 is provided between the second insulating film 15 and the third insulating film 17. The fourth insulating film 21 has a refractive index having a value between the refractive index of the second insulating film 15 and the refractive index of the third insulating film 17. The fourth insulating film 21 is, for example, a silicon oxynitride film. The fourth insulating film 21 includes a portion positioned between the first insulating film 13 and the control electrode 20. For example, the fourth insulating film 21 has a thickness in the Z-direction in the range of 100 to 200 Å at the portion positioned between the second insulating film 15 and the third insulating film 17.

The third insulating film 17 is, for example, a silicon oxide film formed by thermal oxidation of a silicon substrate. For example, the fourth insulating film 21 is formed using CVD and has a film density lower than the film density of the third insulating film 17. For example, the fourth insulating film 21 includes a dangling bond of a silicon atom terminated with hydrogen. For example, when the observation using TEM (transmission electron microscopy) is performed, the fourth insulating film 21 exhibits higher brightness than the brightness of the third insulating film 17.

In the embodiment, the influence of the stress in the second insulating film 15 can be suppressed on the semiconductor substrate 10 by providing the fourth insulating film 21 between the second insulating film 15 and the third insulating film 17. In other words, the lattice strain in the semiconductor substrate 10 can be suppressed; and the dark output of the pixel P_{X} can be reduced. As a result, the sensitivity of the pixel P_{X} can be increased in the solid-state imaging device 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solid-state imaging device, the device comprising:
a light detector provided inside a semiconductor body;
a first insulating film provided on a front surface of the semiconductor body;
a plurality of second insulating films provided between the light detector and the first insulating film, the plurality of second insulating films arranged in a first direction along the front surface of the semiconductor body; and
a third insulating film provided between the semiconductor body and the second insulating films, the third insulating film having a refractive index lower than a refractive index of the second insulating films.

2. The device according to claim 1, wherein the first and third insulating films are silicon oxide films; and the second insulating films are silicon nitride films.

3. The device according to claim 1, wherein the semiconductor body includes silicon.

4. The device according to claim 1, wherein the light detector has a long side along the first direction and a short side along a second direction along the front surface of the semiconductor body, the second direction crossing the first direction.

5. The device according to claim 1, wherein the plurality of second insulating films are arranged in two rows along the first direction.

6. The device according to claim 1, wherein the plurality of second insulating films each include a portion positioned outside the light detector.

7. The device according to claim 1, further comprising:
a control electrode provided on an outer edge of the light detector,
the third insulating film including first and second portions, the first portion being positioned between the light detector and the second insulating film, the second portion being positioned between the semiconductor body and the control electrode,
the first portion having a film thickness in a third direction thinner than a film thickness of the second portion in the third direction, the third direction being orthogonal to the front surface of the semiconductor body.

8. The device according to claim 7, further comprising:
a light-shielding film provided on the first insulating film,
a transparent region above the light detector, wherein
the light-shielding film is not disposed in the transparent region, and
the control electrode is disposed between the semiconductor body and the light-shielding film.

9. A solid-state imaging device, the device comprising:
a light detector provided inside a semiconductor body;
a first insulating film provided on a front surface of the semiconductor body;
a second insulating film provided between the light detector and the first insulating film; and
a third insulating film provided between the semiconductor body and the second insulating film, the third insulating film having a refractive index lower than a refractive index of the second insulating film,
the second insulating film having a plurality of slits arranged in a first direction along the front surface of the semiconductor body,
the second insulating film having a first length along the first direction, the light detector having a second length along the first direction, the second length being longer than the first length.

10. The device according to claim 9, wherein the plurality of slits also arranged in a second direction along the front surface of the semiconductor body, the second direction crossing the first direction.

11. The device according to claim 9, wherein the second insulating film has a thickness in a third direction orthogonal to the front surface of the semiconductor body, the thickness of the second insulating film being thicker than a depth of slits along the third direction.

12. The device according to claim 9, wherein the plurality of slits have hole configurations; and the slits extend along a third direction perpendicular to the front surface of the semiconductor body.

13. A solid-state imaging device, comprising:
a light detector provided inside a semiconductor body;
a first insulating film provided on a front surface of the semiconductor body;
a second insulating film provided between the light detector and the first insulating film, the second insulating film having a refractive index higher than a refractive index of the first insulating film;
a third insulating film provided between the semiconductor body and the second insulating film, the third insulating film having a refractive index lower than a refractive index of the second insulating film; and
a fourth insulating film provided between the second insulating film and the third insulating film, the fourth insulating film having a refractive index having a value between the refractive index of the second insulating film and the refractive index of the third insulating film.

14. The device according to claim 13, wherein the first and third insulating films are silicon oxide films; the second insulating film is a silicon nitride film; and the fourth insulating film is an oxynitride film.

15. The device according to claim 13, further comprising:
a control electrode provided on an outer edge of the light detector, the first insulating film including a portion covering the control electrode, wherein
the third insulating film includes first and second portions, the first portion of the third insulating film being positioned between the light detector and the second insulating film, the second portion of the third insulating film being positioned between the semiconductor body and the control electrode; and
the fourth insulating film includes first and second portions, the first portion of the fourth insulating film being positioned between the second insulating film and the third insulating film, the second portion of the fourth insulating film being positioned between the first insulating film and the control electrode.
